(19) United States
(12) Patent Application Publication
(10) Pub. No.: US 2021/0004677 A1
(43) Pub. Date: Jan. 7, 2021

(54) DATA COMPRESSION USING JOINTLY TRAINED ENCODER, DECODER, AND PRIOR NEURAL NETWORKS

(71) Applicant: DeepMind Technologies Limited, London (GB)

(72) Inventors: Jacob Lee Menick, London (GB); Alexander Benjamin Graves, London (GB)

(21) Appl. No.: 16/767,010

(22) PCT Filed: Feb. 11, 2019
(86) PCT No.: PCT/EP2019/053322

§ 371 Date: May 26, 2020

Related U.S. Application Data
(60) Provisional application No. 62/628,908, filed on Feb. 9, 2018.

(51) Int. Cl. G06N 3/08; G06N 20/20; G06N 7/00; G06N 3/04; G06N 5/04

(52) U.S. Cl. CPC G06N 3/08; G06N 20/20; G06N 5/046; G06N 3/0454; G06N 7/005

(57) ABSTRACT

Methods, systems, and apparatus, including computer programs encoded on a computer storage medium, for training an encoder neural network, a decoder neural network, and a prior neural network, and using the trained networks for generative modeling, data compression, and data decompression. In one aspect, a method comprises: providing a given observation as input to the encoder neural network to generate parameters of an encoding probability distribution; determining an updated code for the given observation; selecting a code that is assigned to an additional observation; providing the code assigned to the additional observation as input to the prior neural network to generate parameters of a prior probability distribution; sampling latent variables from the encoding probability distribution; providing the latent variables as input to the decoder neural network to generate parameters of an observation probability distribution; and determining gradients of a loss function.

### BACKGROUND

This specification relates to processing data using machine learning models.

Machine learning models receive an input and generate an output, e.g., a predicted output, based on the received input. Some machine learning models are parametric models and generate the output based on the received input and on values of the parameters of the model.

Some machine learning models are deep models that employ multiple layers of models to generate an output for a received input. For example, a deep neural network is a deep machine learning model that includes an output layer and one or more hidden layers that each apply a non-linear transformation to a received input to generate an output.

### SUMMARY

This specification describes a system implemented as computer programs on one or more computers in one or more locations that jointly trains an encoder neural network, a decoder neural network, and a prior neural network.

According to a first aspect there is provided a method for training an encoder neural network, a decoder neural network, and a prior neural network, including: receiving training data for training the encoder neural network, the decoder neural network, and the prior neural network, where the training data includes multiple observations, and where each observation lies in an observation space; assigning a respective initial code to each observation included in the training data, where a code is numerical representation of an observation; training the encoder neural network, the decoder neural network, and the prior neural network on the training data by repeatedly performing the following operations: selecting a batch of training data; for each given observation in the selected batch: providing the given observation as input to the encoder neural network, which is configured to process the given observation in accordance with current parameter values of the encoder neural network to generate as output parameters of a data-conditional encoding probability distribution over a latent state space; determining an updated code for the given observation based on the parameters of the data-conditional encoding probability distribution; assigning the updated code to the given observation; selecting a code that is assigned to an additional observation based on a similarity of the code assigned to the additional observation and the updated code assigned to the given observation; providing the code assigned to the additional observation as input to the prior neural network, which is configured to process the code in accordance with current parameter values of the prior neural network to generate as output parameters of a prior probability distribution over the latent state space; sampling one or more latent variables from the data-conditional encoding probability distribution; providing the latent variables as input to the decoder neural network, which is configured to process the latent variables in accordance with current parameter values of the decoder neural network to generate as output parameters of an observation probability distribution over the observation space; determining a gradient of a loss function, where the loss function is based on: (i) a measure of similarity between the data-conditional encoding probability distribution and the prior probability distribution, and (ii) a likelihood of the given observation based on the observation probability distribution; and adjusting the current parameter values of the encoder neural network, the decoder neural network, and the prior neural network based on the gradient.

In some implementations the data-conditional encoding probability distribution is a Gaussian distribution with a predetermined covariance matrix; and the output of the encoder neural network defines a mean vector of the data-conditional encoding probability distribution.

In some implementations, determining an updated code for the given observation based on the parameters of the data-conditional encoding probability distribution includes determining the updated code to be the mean vector output by the encoder neural network.

In some implementations, selecting a code assigned to an additional observation includes: identifying, from amongst the codes currently assigned to each observation, a predetermined number of codes that are most similar to the updated code assigned to the given observation; and selecting a code randomly from amongst the identified codes.

In some implementations, identifying the predetermined number of codes further includes: determining, for each code of the predetermined number of codes, that the code was not previously selected during a current pass through the training data.

In some implementations, the method further includes, after adjusting the current parameter values of the encoder neural network, the decoder neural network, and the prior neural network based on the gradient for each observation in a batch, for each observation included in the training set: providing the observation as input to the encoder neural network, which is configured to process the observation in accordance with current parameter values of the encoder neural network to generate as output parameters of a data-conditional encoding probability distribution over the latent state space; determining an updated code for the observation based on the parameters of the data-conditional encoding probability distribution; and assigning the updated code to the observation.

In some implementations, the loss function is given by a sum of terms including: (i) a Kullback-Leibler divergence measure between the data-conditional encoding probability distribution and the prior probability distribution, and (ii) a negative logarithm of the likelihood of the given observation based on the observation probability distribution.

In some implementations, assigning an initial code to an observation includes sampling the code from a predetermined probability distribution.

In some implementations, the predetermined probability distribution is a standard Normal probability distribution.

In some implementations, the prior probability distribution is a multi-dimensional probability distribution where each dimension of the prior probability distribution is a Gaussian mixture probability distribution; and the output of the prior neural network includes, for each dimension of the prior probability distribution: (i) a mean parameter, (ii) a standard deviation parameter, and (iii) a weighting parameter, for each component of the Gaussian mixture distribution for the dimension.

In some implementations, the encoder neural network includes a convolutional neural network.

In some implementations, the decoder neural network includes an autoregressive neural network.

In some implementations, the prior neural network includes a feedforward neural network.

According to a second aspect there is provided a method for generating a compressed representation of each observation in a set of observations, the method including: training an encoder neural network, a decoder neural network, and a prior neural network on training data including the set of observations by the previously described method; identifying an ordering of the set of observations; sequentially generating the compressed representation of each observation in the set of observations in accordance with the ordering of the set of observations, including, for each observation: providing the observation as input to the encoder neural network, where the encoder neural network is configured to process the observation in accordance with current parameter values of the encoder neural network to generate as output parameters of a data-conditional encoding probability distribution over a latent state space; sampling one or more latent variables from the latent space in accordance with the encoding probability distribution over the latent space; compressing the latent variables using a prior probability distribution over the latent space corresponding to the observation; determining the compressed representation of the observation based at least in part on the compressed latent variables; determining a prior probability distribution over the latent space corresponding to a next observation that follows the observation in the ordering of the set of observations, including: determining a code for the observation based on the parameters of the encoding probability distribution; providing the code for the observation as input to the prior neural network, which is configured to process the code in accordance with current parameter values of the prior neural network to generate as output parameters of the prior probability distribution over the latent state space corresponding to the next observation.

In some implementations, the ordering of the set of observations is determined during the training of the encoder neural network, the decoder neural network, and the prior neural network.

In some implementations, compressing the latent variables using the prior probability distribution over the latent space corresponding to the observation includes: compressing the latent variables using the prior probability distribution over the latent space corresponding to the observation based on an entropy encoding technique.

In some implementations, the entropy encoding technique is a Huffman coding technique.

In some implementations, determining the compressed representation of the observation based at least in part on the compressed latent variables includes: processing the one or more latent variables using the decoder neural network to generate parameters of an observation probability distribution over an observation space, where each observation in the set of observations lies in the observation space; determining an approximate reconstruction of the observation using the observation probability distribution; determining residual data required for lossless reconstruction of the observation based on a difference between the observation and the approximate reconstruction of the observation; and determining the compressed representation of the observation based at least in part on the residual data.

In some implementations, determining an approximate reconstruction of the observation using the observation probability distribution includes: determining the approximate reconstruction of the observation based on the parameters of the observation probability distribution.

In some implementations, determining the compressed representation of the observation based at least in part on the residual data includes compressing the residual data.

In some implementations, the method further includes transmitting or storing the compressed representations of the observations.

In some implementations, the method further includes transmitting or storing current parameters values of the encoder neural network, the decoder neural network, and the prior neural network along with the compressed representations of the observations.

According to a third aspect there is provided a data encoder for generating a compressed representation of each observation in a set of observations, where the data encoder is configured to perform operations including: training an encoder neural network, a decoder neural network, and a prior neural network on training data including the set of observations by the method of the first aspect; identifying an ordering of the set of observations; sequentially generating the compressed representation of each observation in the set of observations in accordance with the ordering of the set of observations, including, for each observation: providing the observation as input to the encoder neural network, where the encoder neural network is configured to process the observation in accordance with current parameter values of the encoder neural network to generate as output parameters of a data-conditional encoding probability distribution over a latent state space; sampling one or more latent variables from the latent space in accordance with the encoding probability distribution over the latent space; compressing the latent variables using a prior probability distribution over the latent space corresponding to the observation; determining the compressed representation of the observation based at least in part on the compressed latent variables; determining a prior probability distribution over the latent space corresponding to a next observation that follows the observation in the ordering of the set of observations, including: determining a code for the observation based on the parameters of the encoding probability distribution; providing the code for the observation as input to the prior neural network, which is configured to process the code in accordance with current parameter values of the prior neural network to generate as output parameters of the prior probability distribution over the latent state space corresponding to the next observation.

According to a fourth aspect, there is provided a method for decompressing a compressed representation of each observation in an ordered sequence of observations, where the compressed representations of the observations have been generated by the method of the second aspect, the method including: receiving current parameter values of an encoder neural network, a decoder neural network, and a prior neural network which have been trained on training data including the set of observations by the method of the first aspect; sequentially decompressing the compressed representation of each observation in the set of observations in accordance with the ordering of the set of observations, including, for each observation: decompressing a compressed representation of one or more latent variables that is included in the compressed representation of the observation using a prior probability distribution corresponding to the observation, where each latent variable lies in a latent space and the prior probability distribution is a probability distribution over the latent space; providing the latent variables as input to the decoder neural network, which is configured to process the latent variables in accordance with current parameter values of the decoder neural network to generate as output parameters of an observation probability distribution over an observation space, where each observation in the ordered sequence of observations lies in the observation space; determining a reconstruction of the observation based at least in part on the observation probability distribution; determining a prior probability distribution over the latent space corresponding to a next observation that follows the observation in the ordering of the set of observations, including: providing the reconstruction of the observation as input to the encoder neural network, where the encoder neural network is configured to process the reconstruction of the observation in accordance with current parameter values of the encoder neural network to generate as output parameters of a data-conditional encoding probability distribution over the latent space; determining a code for the observation based on the parameters of the encoding probability distribution; and providing the code for the observation as input to the prior neural network, which is configured to process the code in accordance with current parameter values of the prior neural network to generate as output parameters of a prior probability distribution over the latent state space corresponding to the next observation.

In some implementations, decompressing the compressed representation of one or more latent variables that is included in the compressed representation of the observation includes: decompressing the compressed representation of the one or more latent variables by inverting a compression procedure used to generate the compressed representation of the one or more latent variables.

In some implementations, the compression procedure is an entropy encoding procedure.

In some implementations, determining the reconstruction of the observation based at least in part on the observation probability distribution includes: determining an approximate reconstruction of the observation using the observation probability distribution; determining the reconstruction of the observation based on: (i) the approximate reconstruction of the observation, and (ii) residual data required for lossless reconstruction of the observation based on a difference between the observation and the approximate reconstruction of the observation, where the residual data is included in the compressed representation of the observation.

In some implementations, determining the approximate reconstruction of the observation using the observation probability distribution includes: determining the approximate reconstruction of the observation based on the parameters of the observation probability distribution.

In some implementations, the compressed representation of the observation includes a compressed representation of the residual data.

In some implementations, the compressed representations of the observations are received over a data communication network or retrieved from a data store.

According to a fifth aspect, there is provided a data decoder for decompressing a compressed representation of each observation in an ordered sequence of observations, where the compressed representations of the observations have been generated by the method of the second aspect, where the data decoder is configured to perform operations including: receiving current parameter values of an encoder neural network, a decoder neural network, and a prior neural network which have been trained on training data including the set of observations by the method of the first aspect; sequentially decompressing the compressed representation of each observation in the set of observations in accordance with the ordering of the set of observations, including, for each observation: decompressing a compressed representation of one or more latent variables that is included in the compressed representation of the observation using a prior probability distribution corresponding to the observation, where each latent variable lies in a latent space and the prior probability distribution is a probability distribution over the latent space; providing the latent variables as input to the decoder neural network, which is configured to process the latent variables in accordance with current parameter values of the decoder neural network to generate as output parameters of an observation probability distribution over an observation space, where each observation in the ordered sequence of observations lies in the observation space; determining a reconstruction of the observation based at least in part on the observation probability distribution; determining a prior probability distribution over the latent space corresponding to a next observation that follows the observation in the ordering of the set of observations, including: providing the reconstruction of the observation as input to the encoder neural network, where the encoder neural network is configured to process the reconstruction of the observation in accordance with current parameter values of the encoder neural network to generate as output parameters of a data-conditional encoding probability distribution over the latent space; determining a code for the observation based on the parameters of the encoding probability distribution; and providing the code for the observation as input to the prior neural network, which is configured to process the code in accordance with current parameter values of the prior neural network to generate as output parameters of a prior probability distribution over the latent state space corresponding to the next observation.

According to a sixth aspect, there is provided a method for generating a sequence of observations, the method including, for each time step after a first time step: providing an observation of a preceding time step as input to an encoder neural network, where the encoder neural network is configured to process the observation of the preceding time step in accordance with current parameter values of the encoder neural network to generate as output parameters of a data-conditional encoding probability distribution over a latent state space; determining a code for the observation of the preceding time step based on the parameters of the data-conditional probability distribution; providing the code as input to a prior neural network, where the prior neural network is configured to process the code in accordance with current parameter values of the prior neural network to generate as output parameters of a prior probability distribution over the latent state space; sampling one or more latent variables from the prior probability distribution; providing the latent variables as input to a decoder neural network, where the decoder neural network is configured to process the latent variables in accordance with current parameter values of the decoder neural network to generate as output parameters of an observation probability distribution over an observation space; and generating an observation for the current time step by sampling from the observation probability distribution.

In some implementations, the method further includes receiving an initial observation for the first time step.

In some implementations, the method further includes, for the first time step: sampling a code from a probability distribution over a space of codes; providing the code as input to the prior neural network, where the prior neural network processes the code in accordance with current parameter values of the prior neural network to generate as output parameters of a prior probability distribution over the latent state space; sampling one or more latent variables from the prior probability distribution; providing the latent variables as input to the decoder neural network, where the decoder neural network processes the latent variables in accordance with current parameter values of the decoder neural network to generate as output parameters of an observation probability distribution over an observation space; and generating an observation for the first time step by sampling from the observation probability distribution.

In some implementations, the data-conditional encoding probability distribution is a Gaussian distribution with a predetermined covariance matrix, the output of the encoder neural network includes a mean vector of the data-conditional probability distribution, and determining a code for the observation based on the parameters of the data-conditional probability distribution includes determining the code to be the mean vector output by the encoder neural network.

In some implementations, the prior probability distribution is a multi-dimensional probability distribution where each dimension of the prior probability distribution is a Gaussian mixture probability distribution, and the output of the prior neural network includes, for each dimension of the prior probability distribution: (i) a mean parameter, (ii) a standard deviation parameter, and (iii) a weighting parameter, for each component of the Gaussian mixture distribution for the dimension.

In some implementations, the encoder neural network is a convolutional neural network.

In some implementations, the decoder neural network is an autoregressive model.

In some implementations, the prior neural network is a feedforward neural network.

In some implementations, the encoder neural network, the decoder neural network, and the prior neural network are trained by the training method of the first aspect.

In some implementations, the observations comprise image data and/or sound data.

According to a seventh aspect, there are provided one or more computer storage media storing instructions that when executed by one or more computers cause the one or more computers to implement the operations of any of the previously described methods.

According to an eighth aspect, there is provided a system including one or more computers and one or more storage devices storing instructions that when executed by the one or more computers cause the one or more computers to implement the operations of the method of any of the previously described methods.

Particular embodiments of the subject matter described in this specification can be implemented so as to realize one or more of the following advantages.

The system described in this specification trains a prior neural network in tandem with an encoder neural network and a decoder neural network in a variational autoencoder framework. The system uses the prior neural network to generate prior probability distributions used to model respective “codes” that represent each observation in a set of training data. The prior probability distribution for a given code representing a given observation is conditioned on a similar code representing a different observation in the training data. In contrast, in conventional variational autoencoder systems, the prior probability distribution is a predetermined probability distribution that is the same for each code. Training the prior neural network naturally induces an ordering of the observations in the set of training data based on the similarity of the respective codes representing the observations. A compression system can use the ordering of the observations in the training data to effectively compress the training data. In particular, the compression system can compress the training data more effectively (i.e., at a higher compression rate) than if the compression system used encoder and decoder neural networks trained using a conventional variational autoencoder system (e.g., without the prior neural network).

The codes representing the observations in the training data that are generated during training of the encoder, decoder, and prior neural networks are rich and informative, and can be used for any of a variety of purposes. For example, the codes can be used to train a classification system that is configured to process a code that represents an observation to generate an output that defines a predicted class of the observation. As another example, the codes can be used by a clustering system to cluster observations, that is, to assign each observation in a set of observations to a respective group of observations that share similar characteristics. Due to being rich and informative, the codes can reduce consumption of computational resources (e.g., memory and computing power) in classification systems, clustering systems, or any other system that uses the codes. For example, a classification system that processes the codes generated by the system described in this specification may be trained to achieve an acceptable classification accuracy over fewer training iterations than would otherwise be necessary. As another example, a clustering system that processes the codes generated by the system described in this specification can effectively cluster a set of observations over fewer clustering iterations than would otherwise be necessary. In these examples the classification or clustering system may be configured to perform an image or sound processing task in which case an output of the system may comprise class labels and/or space/time location data for input data items; or a speech recognition task, in which case an output may comprise recognized words, wordpieces, or phrases in a natural language.

Once trained, the system as described in this specification can generate linked trajectories of observations. Each observation in the trajectory is related (e.g., visually or semantically) to the preceding observation in the trajectory. Such trajectories of linked observations may simulate the evolution of an environment, and may thus be provided to reinforcement learning agents to predict the possible effects of different actions. By predicting the effects of possible actions, a reinforcement learning agent can select actions that enable it to accomplish tasks more effectively (e.g., more quickly). For example a system as described herein may be incorporated into a reinforcement learning system configured to select actions for an electromechanical agent in response to the observations of a real-world environment.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 shows an example training system.

FIG. 2 is a flow diagram of an example process for jointly training an encoder neural network, a decoder neural network, and a prior neural network.

FIG. 3 is a flow diagram of an example process for using the trained encoder, decoder, and prior neural networks to generate a trajectory of new observations.

FIG. 4 is a flow diagram of an example process for using the trained encoder, decoder, and prior neural networks to compress the observations of the training data.

FIG. 5 is a flow diagram of an example process for using the trained encoder, decoder, and prior neural networks to decompress compressed representations of the observations of the training data.

Like reference numbers and designations in the various drawings indicate like elements.

### DETAILED DESCRIPTION

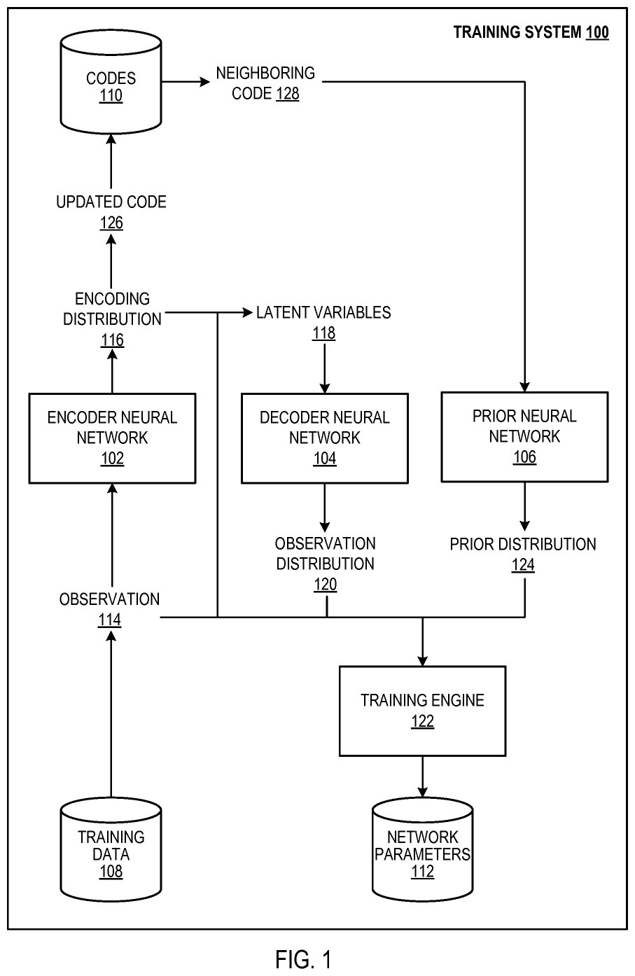

FIG. 1 shows an example training system 100. The training system 100 is an example of a system implemented as computer programs on one or more computers in one or more locations in which the systems, components, and techniques described below are implemented.

The training system 100 is configured to jointly train an encoder neural network 102, a decoder neural network 104, and a prior neural network 106 based on a set of training data 108 which includes multiple “observations”. In the description which follows, the phrase “joint training” should be understood to refer to the joint training of the encoder neural network 102, the decoder neural network 104, and the prior neural network 106.

The observations of the training data 108 can represent any appropriate form of data, for example, text segments, audio data segments, or images. In this specification, the observations are said to belong to an “observation space” of possible observations. For example, if the observations are images, the observation space may be a space representing the space of possible images. In a particular example, if the observations are N×N images, then the observation space may be an N² dimensional space. In another particular example, if the observations are audio data segments with N audio data samples, then the observation space may be an N dimensional space.

To perform the joint training, the system 100 iteratively processes batches (i.e., sets) of one or more observations from the training data 108 over multiple training iterations. After processing a batch of training data, the system 100 updates the network parameters 112 of the encoder neural network 102, the decoder neural network 104, and the prior neural network 106 using gradients of a loss function, as will be described in more detail later.

During the joint training, the training system 100 generates a respective code 110 for each observation in the training data 108. The code 110 for an observation is a numerical representation of the observation. A numerical representation of an observation is an ordered collection of numerical values that represents the observation e.g., a vector, matrix, or higher order tensor of numerical values. The code 110 for an observation generally has a lower dimensionality than the observation itself.

Prior to the joint training, the system 100 assigns a respective initial code to each observation included in the training data 108. For example, the system 100 may assign a respective initial code to each observation by sampling the code from a predetermined probability distribution over the space of possible codes.

At each training iteration, the system selects a batch of observations 114 from the training data 108, and processes the observations 114 using the encoder neural network 102. The encoder neural network 102 is configured to process an observation to generate an output that defines the parameters of an encoding distribution 116 (sometimes referred to as a “data conditional” encoding distribution) for the observation. The encoding distribution 116 is a probability distribution over a latent (state) space that represents a space of possible latent variables. Each latent variable can be represented in as an ordered collection of numerical values, for example, as a vector, matrix, or higher order tensor of numerical values. For each of the observations 114, the system 100 uses the encoding distribution for the observation to: (i) determine an updated code 126 for the observation based on the encoding distribution, and (ii) sample one or more latent variables 118 from the latent space in accordance with encoding distribution.

For each of the observations 114, the system 100 processes the latent variables 118 sampled in accordance with the encoding distribution 116 for the observation using the decoder neural network 104. The decoder neural network 104 is configured to process a latent variable to generate an output which defines values of the parameters of an observation distribution 120. The observation distribution 120 is a probability distribution over the space of possible observations. For example, if the observations are images, then the observation distribution 120 is a probability distribution over the space of possible images. As will be described in more detail later, the training engine 122 uses the observation distribution in determining the updates to the network parameters 112.

The observation distribution 120 over the observation space can be any appropriate probability distribution over the observation space. For example, the observations may be images, the observation space may be the space of possible images, and the observation distribution may assign a respective probability value to each image in the space of possible images. In particular, the observation distribution may define a respective probability distribution over possible intensity values for each pixel of an image. For example, a probability distribution over possible intensity values for a pixel may be a Normal distribution parameterized by mean and standard deviation parameters. The observation distribution may assign a probability value to an image based on a product, over each pixel of the image, of the likelihood of the intensity value of the pixel according to the probability distribution over possible intensity values for the pixel.

For each given observation 114 in the current batch, after updating the code 110 for the given observation based on the encoding distribution 116, the system 100 identifies a “neighboring” code 128 that represents another observation from the training data 108. For example, the system 100 may determine a respective measure of similarity between the updated code 126 for the given observation and the code for each other observation in the training data 108. The measure of similarity can be any appropriate numerical measure of similarity, for example, a measure of similarity based on the Euclidean distance metric or a cosine similarity measure. Thereafter, the system 100 may randomly sample the neighboring code 128 from a predetermined number of codes with the highest respective measures of similarity with the updated code 126 for the given observation.

The system 100 may identify neighboring codes 128 in a manner that causes each neighboring code 128 to be unique to a particular code 110. More specifically, during the joint training, the system 100 may partition the observations of the training data 108 into multiple disjoint (i.e., non-overlapping) batches. The system 100 may “pass through the training data” by sequentially processing each of the batches over respective training iterations, and then repeat additional passes through the training data with respect to potentially different partitions of the observations of the training data. At each pass through the training data, the system 100 may identify neighboring codes 110 in a manner that causes each neighboring code 128 to be unique to a particular code 110 during the pass through the training data. That is, the system 100 may identify neighboring codes 128 for observations 114 in a manner that causes each code to be a neighbor of exactly one other code during the current pass through the training data 108. For example, the predetermined number of codes from which the system 100 samples the neighboring code 128 may be restricted to include only codes that have not yet been used as neighbors during the current pass through the training data.

By identifying neighboring codes 128 in a manner that causes each neighboring code 128 to be unique to a particular code 110, each pass through the training data defines a respective ordering of the observations of the training data. In particular, for any given observation, the observation before the given observation in the ordering can be defined as the observation represented by the neighboring code of the code representing the given observation. The last observation in the ordering of the observations can be chosen arbitrarily.

The system 100 can exploit the ordering of the observations of the training data in training the prior neural network 106. Rather than having a constant prior probability distribution over the latent space, the prior neural network can generate a prior probability distribution that models the code for a given observation conditioned on the code for the preceding observation in the ordering.

For each of the observations 114 in the current batch, the system 100 processes the neighboring code 128 for the observation using the prior neural network 106. The prior neural network 106 is configured to process the neighboring code to generate an output that includes the parameters of a prior probability distribution 124 that models the code for the observation. Like the encoding probability distribution 116, the prior probability distribution 124 is a probability distribution over the latent space.

The training engine 122 determines updates to the current values of the network parameters 112 of the encoder neural network 102, the decoder neural network 104, and the prior neural network 106 using gradients of a loss function. The loss function depends on the encoding distributions 116, the observation distributions 120, and the prior distributions 124 generated for the observations 114 in the current batch. More specifically, for each observation 114, the loss function is based on: (i) a measure of similarity between the encoding distribution 116 and the prior distribution 124, and (ii) a likelihood of the observation 114 based on the observation distribution 120. Broadly, the training engine 122 jointly adjusts the current values of the network parameters 112 to encourage two effects. First, the training engine 122 adjusts the current values of the network parameters 112 to encourage the encoding distribution 116 to be more similar (under some appropriate measure of similarity) to the prior distribution 124. Second, the training engine 122 adjusts the current values of the network parameters 112 to encourage the observation distribution 120 to associate a higher likelihood to the observation 114.

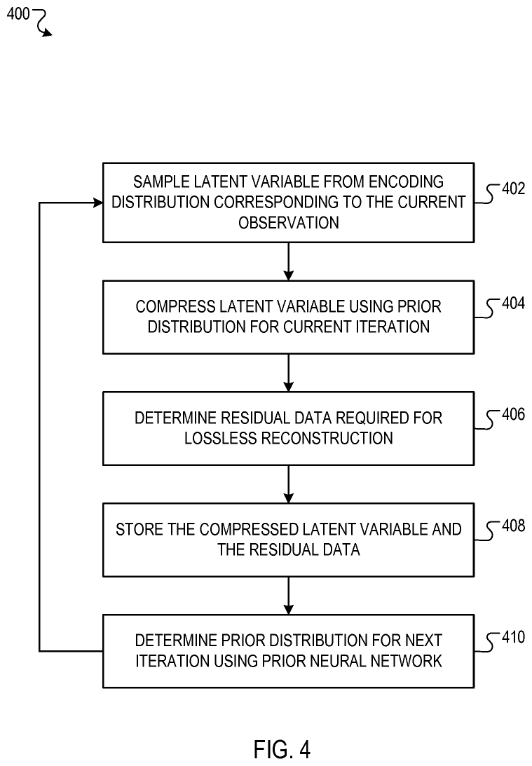

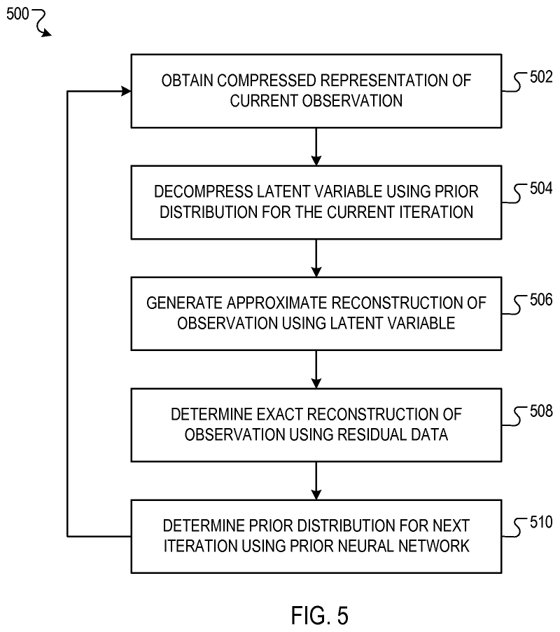

After the joint training, the trained encoder, decoder, and prior neural networks can be used by a compression system and a decompression system. The compression system can use the trained neural networks to generate a compressed representation of the training data 108, and the decompression system 100 can use the trained neural networks to reconstruct the training data 108 from the compressed representation of the training data 108. The compression system can sequentially compress the observations of the training data in accordance with the ordering of the observations defined by the last pass through the training data during the joint training. In particular, after compressing a given observation in the training data, the compression system can process the code for the given observation using the prior neural network to generate the prior probability distribution used to compress the next observation. Analogously, the decompression system can sequentially decompress the observations of the training data in accordance with the ordering of the observations. An example process for using the trained neural networks to compress the observations of the training data is described with reference to FIG. 4. An example process for using the trained neural networks to decompress the observations of the training data is described with reference to FIG. 5.

The codes 110 generated for observations using the trained encoder neural network 102 can be used for any of a variety of purposes. For example, the codes 110 can be used to train a classification system that is configured to process a code 110 that represents an observation to generate an output that defines a predicted class of the observation. In a particular example, the observations may be images, and the class of an observation may define a type of object that is depicted in the image. As another example, the codes 110 can be used to cluster observations, that is, to assign each observation in a set of observations to a respective group of observations that share similar characteristics. In a particular example, observations may be clustered by applying a clustering algorithm (e.g., a k-means or expectation maximization clustering algorithm) to codes generated by processing the observations using the trained encoder neural network.

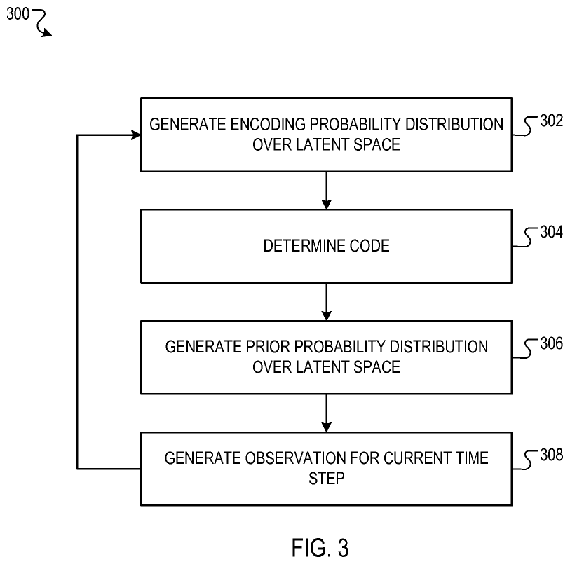

After training, the encoder neural network 102, the decoder neural network 104, and the prior neural network 106 can be used in tandem to generate a trajectory (i.e., a sequence) of new observations. Each observation in the trajectory may be determined based on the preceding observation in the trajectory, and may be related (e.g., visually or semantically) to the preceding observation in the trajectory. Trajectories of new observations generated in this manner can be used by a reinforcement learning agent that is performing actions to interact with an environment to accomplish a task. For example, the agent may be a robotic agent that is interacting with a real-world environment to accomplish a task in an automated manufacturing environment (e.g., the task may be to assemble the components of a manufactured product). The agent may use sensors (e.g., laser or camera sensors) to obtain observations that characterize the current state of the environment. The agent may use trajectories of new observations generated using the encoder, decoder, and prior neural networks to simulate the evolution of the environment, for example, to predict the possible effects of different actions. By predicting the effects of possible actions, the agent can select actions that enable it to accomplish tasks more effectively (e.g., more quickly). An example process for generating a trajectory of new observations is described in more detail with reference to FIG. 3.

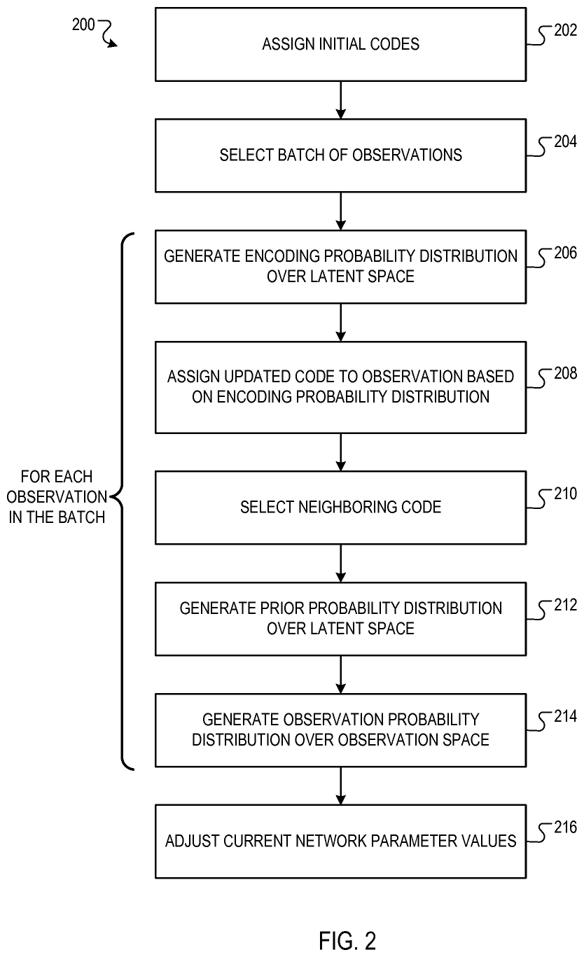

FIG. 2 is a flow diagram of an example process 200 for jointly training an encoder neural network, a decoder neural network, and a prior neural network. For convenience, the process 200 will be described as being performed by a system of one or more computers located in one or more locations. For example, a training system, e.g., the training system 100 of FIG. 1, appropriately programmed in accordance with this specification, can perform the process 200.

The system assigns a respective initial code to each observation in a set of training data that includes multiple observations (202). For example, the system may assign a respective initial code to each observation by sampling the code from a probability distribution over the space of possible codes. In a particular example, the probability distribution over the space of possible codes may be a multi-dimensional standard Normal (i.e., Gaussian) probability distribution, that is, a Normal distribution where each component has mean 0, and where the covariance matrix is a diagonal matrix with only is on the diagonal. In this example, the dimensionality of the standard Normal probability distribution would be equal to the dimensionality of the space of possible codes. “Assigning” a code to an observation refers to generating and storing data that associates the code to the observation. For example, the system may generate and store data that associates the code to the observation in a data store that is a logical data storage area or a physical data storage device.

The subsequent steps 204-216 of the process 200 correspond to a single training iteration. The system can train the encoder neural network, the decoder neural network, and the prior neural network by performing multiple training iterations until a training termination criterion is met (as will be described in more detail below). For convenience, the description of the steps 204-216 which follows will refer to a “current” training iteration, which can be understood to be any of the multiple training iterations.

The system selects a batch of one or more observations from a set of training data that includes multiple observations (204). For example, the system may randomly sample a batch of one or more observations from the set of training data. As another example, the system may select a batch of one or more observations that was determined at the start of the current pass through the training data and which was not yet processed during the current pass through the training data (as described earlier). The observations of the training data can represent any appropriate form of data, for example, text segments, audio data segments, or images.

The system performs steps 206-214 for each observation in the selected batch of one or more observations. For convenience, each of the steps 206-214 is described with reference to a given observation from the selected batch of one or more observations.

The system provides the given observation as input to the encoder neural network (step 206). The encoder neural network is configured to process the given observation in accordance with current parameter values of the encoder neural network to generate as output parameters of an encoding probability distribution over the latent space (206). For example, the encoding probability distribution may be a multi-dimensional Normal distribution with a predetermined covariance matrix (e.g., a diagonal covariance matrix with only is on the diagonal) and with a mean defined by the output of the encoder neural network. In this example, the value of each component of the mean of the encoding probability distribution may be defined by the activation of a respective neuron of the output layer of the encoder neural network in response to processing the given observation. The encoder neural network can have any appropriate neural network architecture. In a particular example, the observations may be images and the encoder neural network may have the architecture of a VGG-style classification neural network (e.g. arXiv1409.1556).

The system assigns an updated code to the given observation based on the parameters of the encoding probability distribution over the latent space (208). For example, the system may assign an updated code to the given observation that is given by a vector representing the mean of the encoding probability distribution.

The system selects a “neighboring” code that is assigned to an additional observation (i.e., that is different than the given observation) based on a similarity of the neighboring code to the updated code assigned to the given observation (210). For example, the system may identify a predetermined number of candidate neighboring codes that are most similar to the updated code assigned to the given observation from among the codes currently assigned to each observation, and then randomly sample the neighboring code from the set of candidate neighboring codes. More specifically, the system may determine a respective measure of similarity between the updated code for the given observation and the current code for each other observation in the training data. Thereafter, the system may identify the set of candidate neighboring codes to be a predetermined number of codes that have the highest measure of similarity to the updated code assigned to the given observation. As described earlier, in some cases, the system includes a particular code in the set of candidate neighboring codes only if the system has not already used the particular code as a neighboring code during the current pass through the training data.

The system provides the neighboring code as input to the prior neural network, which is configured to process the neighboring code in accordance with current parameter values of the prior neural network to generate as output parameters of a prior probability distribution over the latent space (212). For example, the prior probability distribution may be an independent mixture probability distribution. That is, the prior probability distribution may associate a respective mixture probability distribution to each dimension of the latent space, where the mixture probability distributions associated with each dimension of the latent space are independent from one another. A mixture probability distribution refers to a probability distribution with a cumulative distribution function (CDF) that can be expressed as a weighted sum of component CDFs. In a particular example, the prior probability distribution may be a Gaussian mixture probability distribution with a probability density function (PDF) given by:

$$p ( z \vert c ) = {\prod }_{d = 1}^{D} {\sum }_{m = 1}^{M} {π}_{m}^{d} 𝒩 ( {z}^{d} \vert {μ}_{m}^{d} , {σ}_{m}^{d} ) \qquad ( 1 )$$

where p(z|c) is the value of the PDF evaluated at point z in the latent space, D is the dimensionality of the latent space, M is the number of mixture components for each dimension of the latent space, πₘ^{d} is a constant mixing coefficient (or “weighting parameter”) associated with the m-th mixture component of the d-th dimension of the latent space, z^{d} is the d-th component of z, and [symbol] (z^{d}|μₘ^{d}, σₘ^{d}) is the PDF of a Normal random variable with mean μₘ^{d} and standard deviation σₘ^{d} evaluated at z^{d}. In this example, the parameters of the prior probability distribution generated by the prior neural network may include the mixing coefficient, mean, and standard deviation parameters associated with each mixture component of each dimension of the latent space.

The value of each parameter of the prior probability distribution may be defined by the activation of a respective neuron of the output layer of the prior neural network in response to processing the neighboring code. The prior neural network can have any appropriate neural network architecture. In a particular example, the prior neural network may be a feedforward multi-layer perceptron with three hidden layers each containing tan h units, skip connections from the input to all hidden layers, and skip connections from all hidden layers to the output layer.

The system uses the decoder neural network to generate the parameters of an observation probability distribution over the observation space (214). More specifically, the system samples one or more latent variables from the latent space in accordance with the encoding probability distribution over the latent space, and provides the sampled latent variables to the decoder neural network. The decoder neural network is configured to process the sampled latent variables in accordance with current parameter values of the decoder neural network to generate the parameters of the observation distribution over the observation space. The decoder neural network can have any appropriate decoder neural network architecture; for example it may comprise an autoregressive neural network. In a particular example, the observations may be images and the decoder neural network may have e.g. the architecture of an autoregressive Gated PixelCNN neural network (e.g. arXiv:1606.05328). In another example the observations may be audio waveforms and the decoder neural network may have e.g. the architecture of an autoregressive WaveNet (e.g. arXiv:1609:03499).

The system adjusts the current parameter values of the encoder neural network, the decoder neural network, and the prior neural network using gradients of a loss function that depends on the encoding distribution, the observation distribution, and the prior distribution generated for each observation in the current batch (216). More specifically, the loss function may be based on: (i) a measure of similarity between the encoding probability distribution and the prior probability distribution, and (ii) a likelihood of the given observation based on the observation probability distribution. In a particular example, the loss function may be given by:

$$ℒ = {\sum }_{i = 1}^{I} KL [ {q}_{i} ( {z}_{i} \vert {x}_{i} ) , {p}_{i} ( {z}_{i} \vert ) ] - log {r}_{i} ( {x}_{i} \vert {z}_{i} ) \qquad ( 2 )$$

where i indexes the observations in the current batch, I is the total number of observations in the current batch, KL[qᵢ(zᵢ|xᵢ),pᵢ(zᵢ [symbol] )] represents the Kullback-Leibler divergence between the encoding probability distribution qᵢ(zᵢ|xᵢ) and the prior probability distribution pᵢ(zᵢ| [symbol] ) generated for the i-th observation in the current batch, and rᵢ(xᵢ|zᵢ) represents the likelihood of the i-th observation based on the observation probability distribution generated for the i-th observation in the current batch.

The system may determine the gradients of the loss function with respect to the parameters of the encoder neural network, the decoder neural network, and the prior neural network in any appropriate manner, for example, using backpropagation. The system may adjust the current parameter values of the encoder neural network, the decoder neural network, and the prior neural network using the gradients of the loss function based on the update rule associated with any appropriate gradient descent optimization algorithm (e.g., Adam or RMSprop).

After adjusting the current values of the encoder neural network, the decoder neural network, and the prior neural network, the system may determine whether a training termination criterion is met. For example, the training termination criterion may be that a predetermined number of training iterations have been performed, or that a change in the value of the loss function between training iterations falls below a predetermined threshold. In response to determining that a training termination criterion has not been met, the system can perform another training iteration by repeating steps 204-216. In response to determining that a training termination criterion has been met, the system can output the trained parameter values of the encoder neural network, the decoder neural network, the prior neural network, and the current values of the codes assigned to each observation in the training data.

In some cases, before performing another training iteration, the system can update the respective codes assigned to each observation in the training data in accordance with the adjusted values of the encoder neural network parameters. In particular, for each given observation in the training data, the system can process the given observation using the encoder neural network to generate the parameters of a respective encoding probability distribution over the latent space. Thereafter, the system can determine the updated code for the given observation based on the parameters of the encoding probability distribution (e.g., as described with reference to 208), and assign the updated code to the given observation.

Generally, the system can perform certain steps of the process 200 in any of a variety of orders. For example, the system can generate the observation probability distribution (i.e., as described with reference to 214) immediately after generating the encoding probability distribution over the latent space (i.e., as described with reference to 206). The ordering of the steps of the process 200 described in this specification should not be construed as limiting the order in which the system can perform the steps of the process 200.

FIG. 3 is a flow diagram of an example process 300 for using the trained encoder, decoder, and prior neural networks to generate a trajectory of new observations, where each observation in the trajectory is determined based on the preceding observation in the trajectory. For convenience, the process 300 will be described as being performed by a system of one or more computers located in one or more locations. The process 300 is an iterative process that can be used to generate a new observation at each iteration. For convenience, each iteration of the process 300 can be referred to as a “time step”.

The system generates the parameters of an encoding probability distribution over the latent space by processing an observation using the encoder neural network (302). If the current iteration is after the first iteration of the process 300, then the observation processed by the encoder neural network may be the observation generated by the system at the previous iteration of the process 300. If the current iteration is the first iteration of the process 300, then the observation processed by the encoder neural network may be an initial observation that is provided to the system.

The system determines a code for the observation processed by the encoder neural network at the current iteration based on the parameters of the encoding probability distribution over the latent space (304). An example of determining a code for an observation based on the parameters of the encoding probability distribution is described in more detail with reference to step 208 of FIG. 2.

The system generates a prior probability distribution over the latent space by processing the code for the observation using the prior neural network (306). An example of generating a prior probability distribution over the latent space by processing a code using the prior neural network is described in more detail with reference to step 212 of FIG. 2.

The system generates an observation by sampling from an observation probability distribution over the observation space of possible observations (308). The system generates the observation probability distribution by processing one or more latent variables that are sampled from the latent space in accordance with the prior probability distribution using the decoder neural network. An example of generating an observation probability distribution by processing latent variables using the decoder neural network is described in more detail with reference to step 214 of FIG. 2.

After generating the observation at the current time step, the system can determine whether a termination criterion is met. For example, the termination criterion may be that the system has generated a predetermined number of new observations by performing a predetermined number of iterations of the process 300. In response to determining that a termination criterion is not met, the system can repeat the steps of the process 300 to generate another new observation. In response to determining that a training termination criterion is met, the system can output the trajectory of generated observations.

In some cases, rather than receiving an initial observation from an external source at the first iteration of the process 300, the system can internally generate the initial observation. More specifically, the system can sample a code from a probability distribution over the space of possible codes. The probability distribution over the space of possible codes may be generated by fitting a probability distribution (e.g., a mixture of Normal distributions) to the set of codes corresponding to observations in the set of training data used to train the encoder, decoder, and prior neural networks. After sampling the code, the system can the operations described with reference to 306 and 308 to generate the initial observation from the sampled code.

FIG. 4 is a flow diagram of an example process 400 for using the trained encoder, decoder, and prior neural networks to compress the observations of the training data used to train the neural networks. The description of the process 400 assumes that during training of the encoder, decoder, and prior neural networks, the neighboring code of each code was selected to be unique. In this case, each pass through the training data during the training procedure defines a respective ordering of the observations of the training data. In particular, for any given observation, the observation before the given observation in the ordering can be defined as the observation represented by the neighboring code of the code representing the given observation. The “last” observation in the ordering of the observations can be chosen arbitrarily. The ordering of the observations of the training data refers to the ordering defined by the last pass through the training data during the training procedure. For convenience, the process 400 will be described as being performed by a system of one or more computers located in one or more locations. For example, a compression system appropriately programmed in accordance with this specification can perform the process 400.

The process 400 is an iterative procedure that iterates through the observations of the training data, in accordance with the ordering of the observations, starting from the first observation.

The system processes the current observation using the encoder neural network to generate the parameters of an encoding probability distribution over the latent space, and samples one or more latent variables in accordance with the encoding distribution (402). For example, as described earlier, the encoding probability distribution may be a multi-dimensional Normal distribution with a predetermined covariance matrix and with a mean defined by the output of the encoder neural network.

The system compresses the one or more latent variables using a prior probability distribution over the latent space for the current iteration (404). If the current iteration is the first iteration, then the prior probability distribution for the current iteration can be an arbitrary probability distribution over the latent space (e.g., a uniform probability distribution over the latent space). If the current iteration is after the first iteration, then the prior probability distribution for the current iteration is determined by the system at the previous iteration (i.e., as described further with reference to step 410). The system can compress the latent variables using the prior probability distribution in any appropriate manner. For example, the system can use an entropy encoding technique (e.g., Huffman coding or arithmetic coding) to compress the latent variables using the prior probability distribution.

The system determines residual data required for lossless (i.e., exact) reconstruction of the current observation from the latent variables (406). In particular, the system processes the latent variables using the decoder neural network to generate the parameters of an observation probability distribution, and then determines an approximate reconstruction of the current observation using the observation probability distribution. For example, the system may determine the approximate reconstruction of the current observation to be the mean of the observation probability distribution. The system determines the residual data required for lossless reconstruction of the current observation to be data that defines the difference between the current observation and the approximate reconstruction of the current observation. For example, if the observations are images, then the residual data may define a residual image obtained by subtracting the approximate reconstruction of the image from the image itself.

The system stores the compressed latent variable and the residual data as the compressed representation of the current observation (408). In some cases, the system may additionally compress the residual data using an appropriate compression technique (e.g., entropy encoding using a predetermined probability distribution over the observation space). Rather than storing the compressed representation of the current observation, the system can also transmit the compressed representation of the current observation to a receiver over a data communication network (e.g., the Internet).

The system determines the prior distribution over the latent space for the next iteration using the encoding probability distribution generated at the current iteration (410). For example, to determine the prior distribution for the next iteration, the system may determine a code that represents the current observation from the parameters of the encoding distribution. In a particular example, the system may determine the code to be the mean vector of the encoding distribution. Next, the system processes the code using the prior neural network to generate the prior distribution over the latent space for the next iteration.

If the current iteration is the last iteration, then the system can store or transmit the ordered sequence of compressed representations of the observations of the training data. The system may also store or transmit data that defines the parameters of the prior probability distribution over the latent space for the first iteration of the process 400. If the current iteration is not the last iteration, then the system repeats the steps of the process 400 at the next iteration.

FIG. 5 is a flow diagram of an example process 500 for using the trained encoder, decoder, and prior neural networks to decompress compressed representations of the observations of the training data used to train the neural networks. The description of the process 500 assumes that the compressed representations of the observations of the training data are generated in accordance with a compression procedure as described with reference to FIG. 4. In particular, the compressed representations of the observations of the training data are associated with an ordering that is known during the decompression process. For convenience, the process 500 will be described as being performed by a system of one or more computers located in one or more locations. For example, a decompression system appropriately programmed in accordance with this specification can perform the process 500.

The process 500 is an iterative procedure that iterates through the observations of the training data, in accordance with the ordering of the observations, starting from the first observation.

The system obtains a compressed representation of the current observation (502). For example, the system may retrieve the compressed representation of the current observation from a data store, or the system may receive the compressed representation of the current observation over a data communication network (e.g., the Internet). As described with reference to 408, the compressed representation of the current observation includes: (i) a compressed representation of one or more latent variables, and (ii) residual data that required for lossless reconstruction of the current observation from the compressed latent variables.

The system decompresses the compressed representation of the latent variables using a prior probability distribution over the latent space for the current iteration (504). The prior distribution used to decompress the compressed representation of the latent variables is the same probability distribution over the latent space that was used to compress the latent variables (e.g., as described with reference to 404). If the current iteration is the first iteration, then the prior probability distribution for the current iteration may be predetermined (e.g., by being stored or transmitted along with the compressed representations of the observations, as described earlier). If the current iteration is after the first iteration, then the prior probability distribution for the current iteration is determined by the system at the previous iteration (e.g., as described with reference to 510). The system can decompress the compressed representation of the latent variables by inverting the compression procedure (e.g., the entropy encoding procedure) used to generate the compressed representation of the latent variables.

The system generates an approximate reconstruction of the current observation based on the latent variables (506). In particular, the system processes the latent variables using the decoder neural network to generate the parameters of an observation probability distribution, and then determines the approximate reconstruction of the current observation using the observation probability distribution. For example, the system may determine the approximate reconstruction of the current observation to be the mean of the observation probability distribution.

The system determines an exact reconstruction of the current observation by combining the approximate reconstruction of the current observation with the residual data required for lossless reconstruction of the current observation (508). For example, if the current observation is an image, then the residual data may define a residual image that when added (or otherwise combined with) the approximate reconstruction image defines the exact reconstruction of the current observation.

The system determines the prior distribution over the latent space for the next iteration (510). To determine the prior distribution for the next iteration, the system processes the current observation using the encoder neural network to generate the parameters of an encoding probability distribution over the latent space, and determines a code that represents the current observation from the parameters of the encoding distribution. In a particular example, the system may determine the code to be the mean vector of the encoding distribution. Next, the system processes the code using the prior neural network to generate the parameters of the prior distribution over the latent space for the next iteration.

If the current iteration is the last iteration, then the system can output the reconstructions of the observations. If the current iteration is not the last iteration, then the system repeats the steps of the process 500 at the next iteration.

This specification uses the term “configured” in connection with systems and computer program components. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially-generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application-specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, an app, a module, a software module, a script, or code, can be written in any form of programming language, including compiled or interpreted languages, or declarative or procedural languages; and it can be deployed in any form, including as a stand-alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a data communication network.

In this specification the term “engine” is used broadly to refer to a software-based system, subsystem, or process that is programmed to perform one or more specific functions. Generally, an engine will be implemented as one or more software modules or components, installed on one or more computers in one or more locations. In some cases, one or more computers will be dedicated to a particular engine; in other cases, multiple engines can be installed and running on the same computer or computers.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone that is running a messaging application, and receiving responsive messages from the user in return.

Data processing apparatus for implementing machine learning models can also include, for example, special-purpose hardware accelerator units for processing common and compute-intensive parts of machine learning training or production, i.e., inference, workloads.

Machine learning models can be implemented and deployed using a machine learning framework, e.g., a TensorFlow framework, a Microsoft Cognitive Toolkit framework, an Apache Singa framework, or an Apache MXNet framework.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface, a web browser, or an app through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

1. A method for training an encoder neural network, a decoder neural network, and a prior neural network, comprising:
receiving training data for training the encoder neural network, the decoder neural network, and the prior neural network, wherein the training data comprises a plurality of observations, and wherein each observation lies in an observation space;
assigning a respective initial code to each observation included in the training data, wherein a code is numerical representation of an observation;
training the encoder neural network, the decoder neural network, and the prior neural network on the training data by repeatedly performing the following operations:
selecting a batch of training data;
for each given observation in the selected batch:
providing the given observation as input to the encoder neural network, which is configured to process the given observation in accordance with current parameter values of the encoder neural network to generate as output parameters of a data-conditional encoding probability distribution over a latent state space;
determining an updated code for the given observation based on the parameters of the data-conditional encoding probability distribution;
assigning the updated code to the given observation;
selecting a code that is assigned to an additional observation based on a similarity of the code assigned to the additional observation and the updated code assigned to the given observation;
providing the code assigned to the additional observation as input to the prior neural network, which is configured to process the code in accordance with current parameter values of the prior neural network to generate as output parameters of a prior probability distribution over the latent state space;
sampling one or more latent variables from the data-conditional encoding probability distribution;
providing the latent variables as input to the decoder neural network, which is configured to process the latent variables in accordance with current parameter values of the decoder neural network to generate as output parameters of an observation probability distribution over the observation space;
determining a gradient of a loss function, wherein the loss function is based on: (i) a measure of similarity between the data-conditional encoding probability distribution and the prior probability distribution, and (ii) a likelihood of the given observation based on the observation probability distribution; and
adjusting the current parameter values of the encoder neural network, the decoder neural network, and the prior neural network based on the gradient.

2. The method of claim 1, wherein:
the data-conditional encoding probability distribution is a Gaussian distribution with a predetermined covariance matrix; and
the output of the encoder neural network defines a mean vector of the data-conditional encoding probability distribution.

3. The method of claim 1, wherein determining an updated code for the given observation based on the parameters of the data-conditional encoding probability distribution comprises determining the updated code to be the mean vector output by the encoder neural network.

4. The method of claim 1, wherein selecting a code assigned to an additional observation comprises:
identifying, from amongst the codes currently assigned to each observation, a predetermined number of codes that are most similar to the updated code assigned to the given observation; and
selecting a code randomly from amongst the identified codes.

5. The method of claim 4, wherein identifying the predetermined number of codes further comprises:
determining, for each code of the predetermined number of codes, that the code was not previously selected during a current pass through the training data.

6. The method of claim 1, further comprising, after adjusting the current parameter values of the encoder neural network, the decoder neural network, and the prior neural network based on the gradient for each observation in a batch, for each observation included in the training set:
providing the observation as input to the encoder neural network, which is configured to process the observation in accordance with current parameter values of the encoder neural network to generate as output parameters of a data-conditional encoding probability distribution over the latent state space;
determining an updated code for the observation based on the parameters of the data-conditional encoding probability distribution; and
assigning the updated code to the observation.

7. The method of claim 1, wherein the loss function is given by a sum of terms comprising: (i) a Kullback-Leibler divergence measure between the data-conditional encoding probability distribution and the prior probability distribution, and (ii) a negative logarithm of the likelihood of the given observation based on the observation probability distribution.

8. The method of claim 1, wherein assigning an initial code to an observation comprises sampling the code from a predetermined probability distribution.

9. The method of claim 8, wherein the predetermined probability distribution is a standard Normal probability distribution.

10. The method of claim 1, wherein:
the prior probability distribution is a multi-dimensional probability distribution where each dimension of the prior probability distribution is a Gaussian mixture probability distribution; and
the output of the prior neural network comprises, for each dimension of the prior probability distribution: (i) a mean parameter, (ii) a standard deviation parameter, and (iii) a weighting parameter, for each component of the Gaussian mixture distribution for the dimension.

11. The method of claim 1, wherein the encoder neural network comprises a convolutional neural network.

12. The method of claim 1, wherein the decoder neural network comprises an autoregressive neural network.

13. The method of claim 1, wherein the prior neural network comprises a feedforward neural network.

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. One or more non-transitory computer storage media storing instructions that when executed by one or more computers cause the one or more computers to perform operations for training an encoder neural network, a decoder neural network, and a prior neural network, the operations comprising:
receiving training data for training the encoder neural network, the decoder neural network, and the prior neural network, wherein the training data comprises a plurality of observations, and wherein each observation lies in an observation space;
assigning a respective initial code to each observation included in the training data, wherein a code is numerical representation of an observation;
training the encoder neural network, the decoder neural network, and the prior neural network on the training data by repeatedly performing the following operations:
selecting a batch of training data;
for each given observation in the selected batch:
providing the given observation as input to the encoder neural network, which is configured to process the given observation in accordance with current parameter values of the encoder neural network to generate as output parameters of a data-conditional encoding probability distribution over a latent state space;
determining an updated code for the given observation based on the parameters of the data-conditional encoding probability distribution;
assigning the updated code to the given observation;
selecting a code that is assigned to an additional observation based on a similarity of the code assigned to the additional observation and the updated code assigned to the given observation;
providing the code assigned to the additional observation as input to the prior neural network, which is configured to process the code in accordance with current parameter values of the prior neural network to generate as output parameters of a prior probability distribution over the latent state space;
sampling one or more latent variables from the data-conditional encoding probability distribution;
providing the latent variables as input to the decoder neural network, which is configured to process the latent variables in accordance with current parameter values of the decoder neural network to generate as output parameters of an observation probability distribution over the observation space;
determining a gradient of a loss function, wherein the loss function is based on: (i) a measure of similarity between the data-conditional encoding probability distribution and the prior probability distribution, and (ii) a likelihood of the given observation based on the observation probability distribution; and
adjusting the current parameter values of the encoder neural network, the decoder neural network, and the prior neural network based on the gradient.

43. A system comprising one or more computers and one or more storage devices storing instructions that when executed by the one or more computers cause the one or more computers to perform operations for training an encoder neural network, a decoder neural network, and a prior neural network, the operations comprising:
receiving training data for training the encoder neural network, the decoder neural network, and the prior neural network, wherein the training data comprises a plurality of observations, and wherein each observation lies in an observation space;
assigning a respective initial code to each observation included in the training data, wherein a code is numerical representation of an observation;
training the encoder neural network, the decoder neural network, and the prior neural network on the training data by repeatedly performing the following operations:
selecting a batch of training data;
for each given observation in the selected batch:
providing the given observation as input to the encoder neural network, which is configured to process the given observation in accordance with current parameter values of the encoder neural network to generate as output parameters of a data-conditional encoding probability distribution over a latent state space;
determining an updated code for the given observation based on the parameters of the data-conditional encoding probability distribution;
assigning the updated code to the given observation;
selecting a code that is assigned to an additional observation based on a similarity of the code assigned to the additional observation and the updated code assigned to the given observation;
providing the code assigned to the additional observation as input to the prior neural network, which is configured to process the code in accordance with current parameter values of the prior neural network to generate as output parameters of a prior probability distribution over the latent state space;
sampling one or more latent variables from the data-conditional encoding probability distribution;
providing the latent variables as input to the decoder neural network, which is configured to process the latent variables in accordance with current parameter values of the decoder neural network to generate as output parameters of an observation probability distribution over the observation space;
determining a gradient of a loss function, wherein the loss function is based on: (i) a measure of similarity between the data-conditional encoding probability distribution and the prior probability distribution, and (ii) a likelihood of the given observation based on the observation probability distribution; and
adjusting the current parameter values of the encoder neural network, the decoder neural network, and the prior neural network based on the gradient.

44. The system of claim 43, wherein:
the data-conditional encoding probability distribution is a Gaussian distribution with a predetermined covariance matrix; and
the output of the encoder neural network defines a mean vector of the data-conditional encoding probability distribution.

45. The system of claim 43, wherein determining an updated code for the given observation based on the parameters of the data-conditional encoding probability distribution comprises determining the updated code to be the mean vector output by the encoder neural network.

46. The system of claim 43, wherein selecting a code assigned to an additional observation comprises:
identifying, from amongst the codes currently assigned to each observation, a predetermined number of codes that are most similar to the updated code assigned to the given observation; and
selecting a code randomly from amongst the identified codes.

47. The system of claim 46, wherein identifying the predetermined number of codes further comprises:
determining, for each code of the predetermined number of codes, that the code was not previously selected during a current pass through the training data.

48. The system of claim 43, further comprising, after adjusting the current parameter values of the encoder neural network, the decoder neural network, and the prior neural network based on the gradient for each observation in a batch, for each observation included in the training set:
providing the observation as input to the encoder neural network, which is configured to process the observation in accordance with current parameter values of the encoder neural network to generate as output parameters of a data-conditional encoding probability distribution over the latent state space;
determining an updated code for the observation based on the parameters of the data-conditional encoding probability distribution; and
assigning the updated code to the observation.
